(19) United States
(12) Patent Application Publication
(10) Pub. No.: US 2026/0038610 A1
(43) Pub. Date: Feb. 5, 2026

(54) LAST WRITTEN PAGE HANDLING FOR OPEN CURSOR BLOCK SCANS IN A MEMORY SUB-SYSTEM

(71) Applicant: Micron Technology, Inc., Boise, ID (US)

(72) Inventors: Fanqi Wu, Sunnyvale, CA (US); Yang Liu, San Jose, CA (US); Zhenlei Shen, Milpitas, CA (US)

(21) Appl. No.: 18/790,885

(22) Filed: Jul. 31, 2024

(51) Int. Cl. G11C 16/34; G11C 16/08

(52) U.S. Cl. CPC G11C 16/3422; G11C 16/08

(57) ABSTRACT

A scan trigger event is detected. Last written page (LWP) data for one or more memory devices of a plurality of memory devices is determined. A scan on one or more pages of the one or more memory devices of the plurality of memory devices is performed based on the LWP data.

### TECHNICAL FIELD

Embodiments of the disclosure relate generally to memory sub-systems, and more specifically, relate to last written page handling for open cursor block scans in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system, in accordance with some embodiments of the present disclosure.

FIG. 2 illustrates a flow diagram of an example method of last written page (LWP) handling for media scans, in accordance with some embodiments of the present disclosure.

FIG. 3 illustrates an example instance of pages written to a plurality of dies, in accordance with some embodiments of the present disclosure.

FIG. 4 illustrates a flow diagram of an example method of last written page (LWP) handling for read disturb scans, in accordance with some embodiments of the present disclosure.

FIG. 5 illustrates an example instance of pages written to and read from a plurality of dies, in accordance with some embodiments of the present disclosure.

FIG. 6 illustrates an example method for last written page (LWP) handling for open cursor block scans, in accordance with some embodiments of the present disclosure.

FIG. 7 illustrates a block diagram of an example computer system in which embodiments of the present disclosure may operate.

### DETAILED DESCRIPTION

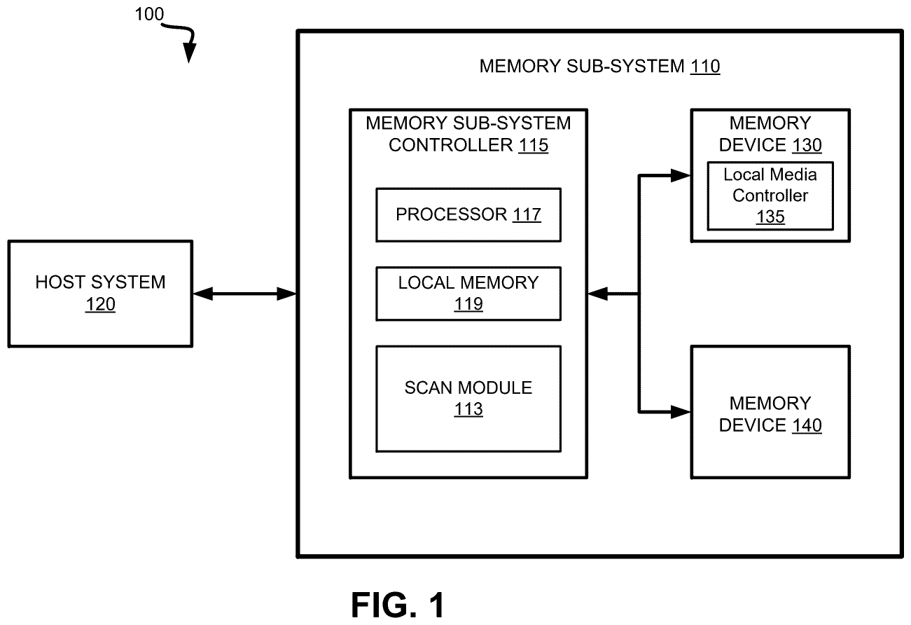

Aspects of the present disclosure are directed to last written page handling for open cursor block scans in a memory sub-system. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

To program (e.g., write) data to a memory device, a certain write size granularity is used. In some cases, where a memory sub-system includes multiple memory devices, data can be programed to respective segments across the multiple memory devices as part of a page stripe. If the programming process is interrupted, or the amount of data being programed does not fill the entire page stripe, it can be possible for some segments associated with certain memory devices to remain unprogrammed. Accordingly, in a sequential programming operation, the last written page (i.e., the segment of the memory device that was most recently programmed) can be different across the multiple memory devices. As part of the normal operation, a scan process periodically runs on the memory sub-system to ensure data integrity. The scan process can be executed by a scan module for media scans and/or read disturb scans in response to the occurrence of respective triggering events. The scan module uses last written page (LWP) data from an open cursor block (e.g., a page stripe that has been partially programmed with host data, a page stripe that is available to be written to) to identify a page or pages of each memory device to be scanned as part of the scan process. However, in traditional implementations of the scan module, the LWP data might not be accurate. For example, all of the segments in a given page stripe may not represent the LWP of the corresponding memory devices.

When information is written to a memory sub-system (e.g., a memory sub-system that uses NAND-type flash memory devices), the smallest unit into which the information can be written is a page. A page is unit of a page stripe and page stripes span across different dies (i.e., memory devices) in the memory sub-system. Conventional systems use the last page stripe onto which information was written as an indication of the LWP data. The scan module uses the LWP data to perform a scan on the page stripe that follows the page stripe identified in the LWP data. However, these systems do not consider whether any pages on the last page stripe that was written to are empty, and thus do not accurately reflect the LWP data for the corresponding memory devices. This can lead to misaligned LWPs since the scan module performs the scan on the page stripe following that identified in the LWP data without determining that the page stripe identified in the LWP data contains empty pages on which the scan should be performed.

When the scan module uses the page stripe to determine where to perform the scan, misaligned LWPs can cause the scan module to identify an incorrect scan location. This can impact at least one of the media scans and/or read disturb scans that are performed on the memory device, which can further impact reliability and a trigger rate. More specifically, scanning the incorrect location can cause scan errors. For example, scanning the incorrect location can lead to mis-NAND detect erase page (mis-NDEP) scans, which determine whether erased pages are healthy enough to be programmed.

Media scans are performed periodically (e.g., at predetermined time intervals) to monitor data retention and detect degradation over time. Media scans are triggered at the predetermined time intervals. Read disturb scans are performed to detect degradation associated with read operations. Read disturb scans are triggered when a read count satisfies (e.g., is equal to) a threshold read count. Both media scans and read disturb scans utilize the described LWP data to identify the page(s) on which a scan should be performed, but can suffer scan errors when the last page stripe does not accurately reflect the actual LWP data for each memory device in the memory sub-system.

Aspects of the present disclosure address the above and other deficiencies by providing a memory sub-system that determines LWP data at a page level per die to protect against LWP misalignment. The proposed handling of LWP data for media scans differs from the proposed handling of LWP data for read disturb scans. Both the media scan and read disturb scan (and associated handling) are described in detail below.

Media scans are triggered at predetermined time intervals. When a media scan is triggered, the LWP of each die is identified. Data indicating the LWP of each die is stored in a data structure (e.g., a firmware table, register, or the like) within the memory device. A scan module determines the LWP of each die by performing lookup operations on the data structure. For each die, the four pages following the LWP are grouped together to create a sub-block candidate group. A page is selected from the sub-block candidate group (referred to herein as a common page) and is used to determine whether the identified LWP is the LWP across all dies or whether the dies are experiencing LWP misalignment. The common page is associated with a page order that indicates the page stripe on which the common page is located. For each die, it is determined whether the common page belongs to the sub-block candidate group associated with the die. In instances where the common page belongs to the sub-block candidate group, the media scan can be performed on the common page. However, in instances where the common page does not belong to the sub-block candidate group, it is determined that the dies are experiencing LWP misalignment. For each die experiencing LWP misalignment, the page order associated with the common page is reduced by four. The media scan can be performed on the page that is located at four less than the page order.

Media scans are performed on empty pages to detect an erase tail associated with each empty page. Read disturbs and/or data retention on a page can cause the erase tail associated with the page to grow. When the erase tail satisfies (e.g., meets or exceeds) a threshold erase tail, then it is no longer safe to program (e.g., write data to) the associated page. If data is written to the associated page and a read operation is performed on the page, then an uncorrectable error correction code (UECC) error can happen, which needs a redundant array of independent NAND (RAIN) to recover the data. Media scans are used to check whether empty pages have healthy erase tails to determine whether the empty pages can be programmed.

Read disturb scans are triggered when a read count satisfies (e.g., is equal to) a threshold read count value. When a read disturb scan is triggered, a scan module identifies a wordline associated with a current read location (e.g., a wordline at which a current read operation is executing). A subsequent wordline (e.g., a wordline that follows the wordline associated with the current read location) is identified. The subsequent wordline is analyzed to determine whether it includes one or more empty pages. In instances where the subsequent wordline does not include an empty page, then a read disturb scan is not performed. However, in instances wherein the subsequent wordline includes at least one empty page, an empty page is selected at random. The read disturb scan is performed on the selected empty page.

Read disturb scans are performed on empty pages to determine whether the pages are associated with healthy erase tails. The erase tail associated with each empty page is used to determine whether the empty page can be programmed safely at some time in the future.

Advantages of the present disclosure include, but are not limited to, utilizing LWP information for each die that is stored within a memory device to perform NDEP scans (e.g., media scans and/or read disturb scans) on empty pages to prevent instances of LWP misalignment. Identifying the LWP of each die at a page level, as opposed to a page stripe level, avoids instances of mis-NDEP scans.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a scan module 113 that can perform one or more NDEP scans (e.g., media scans and/or read disturb scans) on empty pages to assess erase tails associated with each empty page. Based on the erase tail associated with an empty page, scan module 113 can determine whether the empty page can safely be programmed at some time in the future. In some embodiments, the memory sub-system controller 115 includes at least a portion of the scan module 113. In some embodiments, the scan module 113 is part of the host system 120, an application, or an operating system. In other embodiments, local media controller 135 includes at least a portion of scan module 113 and is configured to perform the functionality described herein.

The scan module 113 can communicate with at least local memory 119 to perform lookup up operations on tables and/or registers therein that store the last written page (LWP) of each die. Scan module 113 can use the identified LWP of each die to identify one or more empty pages on which a media scan and/or read disturb scan can be performed. Further details regarding the operations of the scan module 113 are described below.

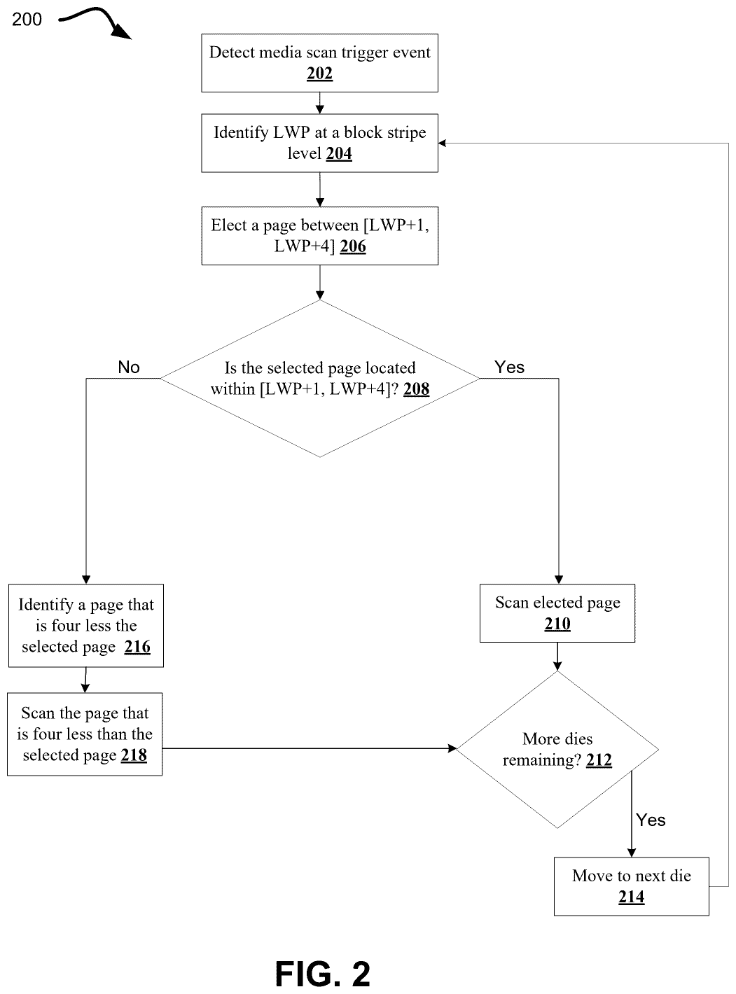

FIG. 2 is a flow diagram of an example method 200 for LWP handling for media scans, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the scan module 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 202, the processing logic (e.g., scan module 113) can detect a media scan trigger event. Media scans can be triggered at predetermined time intervals and/or at the expiration of the predetermined time intervals. For example, the processing logic can utilize a timer or counter that measures the time that has elapsed since a previous media scan was performed in the memory sub-system 110. Once that time reaches the predefined time interval, the processing logic can detect the trigger event.

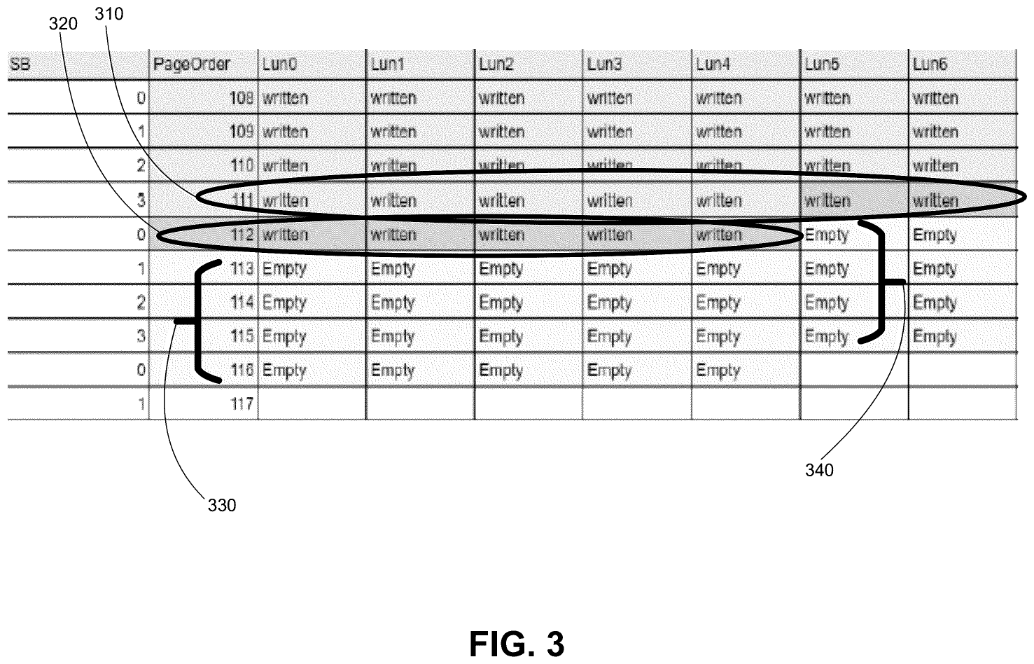

At operation 204, scan module 113 can determine the LWP for each die. In some instances, determining the LWP for each die includes determining the LWP for a page stripe that includes at least one block from each memory device die. Data that indicates the LWP of each die can be stored locally on the memory device (e.g., in local memory 119 of memory sub-system controller 115). Scan module 113 can execute one or more lookup operations on local memory 119 to determine the LWP of each die. FIG. 3 illustrates an example instance of pages written to a plurality of dies, such as memory device 130, in accordance with some embodiments of the present disclosure. Each column in the chart of FIG. 3 (i.e., Lun0, Lun1, Lun2, . . . Lun6) corresponds to a respective die. Each die contains a number of pages, some of which have been programmed and some of which remain unprogrammed. Pages that have been programmed are denoted as “written,” while pages that can be programmed are denoted as “empty.” Each row that spans Lun0 to Lun6 corresponds to a page stripe. As illustrated by element 320, the LWP of Lun0 to Lun4 is in page stripe 112. However, as illustrated by element 310, the LWP of Lun5 to Lun6 is in page stripe 111. Scan module 113 can retrieve this information based on the one or more lookup operations performed on local memory 119.

At operation 206, scan module 113 can identify, for each die, a sub-block candidate group that contains a certain number of pages (e.g., four pages) that follow the LWP. For example, referring to sub-block candidate group 330 of FIG. 3, since page 112 is the LWP, the sub-block candidate group associated with Lun0 can include the empty pages 113 to 116. As another example, referring to sub-block candidate group 340 of FIG. 3, since page 111 is the LWP, the sub-block candidate group associated with Lun5 can include the empty pages 112 to 115. Scan module 113 can select, at random, a page within the sub-block candidate group 330, referred to herein as the common page. For example, scan module 113 can select page 116 as the common page.

At operation 208, scan module 113 can determine, for each die, whether the common page is included in the identified sub-block candidate group of that die. For example, referring to FIG. 3, for Lun0, scan module 113 can determine whether the common page is included in sub-block candidate group 330.

If, at operation 208, scan module 113 determines that the common page is included in the sub-block candidate group, then, at operation 210, scan module 113 can perform the media scan on the common page. For example, referring to FIG. 3, scan module 113 can determine that the common page is included in sub-block candidate group 330 and can scan the common page.

At operation 212, scan module 113 can determine whether the memory sub-system includes additional dies. If, at operation 212, scan module 113 determines that the memory sub-system includes additional dies, then, at operation 214, scan module 113 can move sequentially to the next die and return to operation 204.

Returning to the discussion of operation 208, scan module 113 may determine that the common page is not included in the sub-block candidate group. For example, referring to FIG. 3, scan module 113 can determine that the common page 116 is not included in sub-block candidate group 340.

If, at operation 208, scan module 113 determines that the common page is not included in the sub-block candidate group, then, at operation 216, scan module 113 can reduce the page order of the common page to identify a page that corresponds to four less than the common page. For example, referring to FIG. 3, scan module 113 can reduce the page order of the common page by four, which corresponds to page 112.

At operation 218, scan module 113 can scan the page that is associated with a page order that is four less than the common page. For example, referring to FIG. 3, scan module 113 can scan the empty page 112.

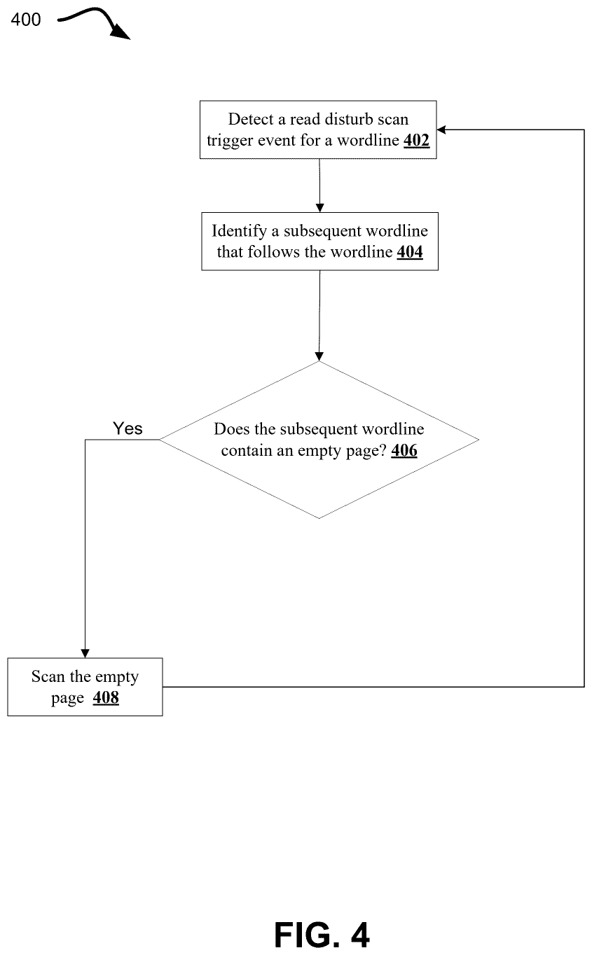

FIG. 4 is a flow diagram of an example method 400 for last written page (LWP) handling for read disturb scans, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the scan module 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

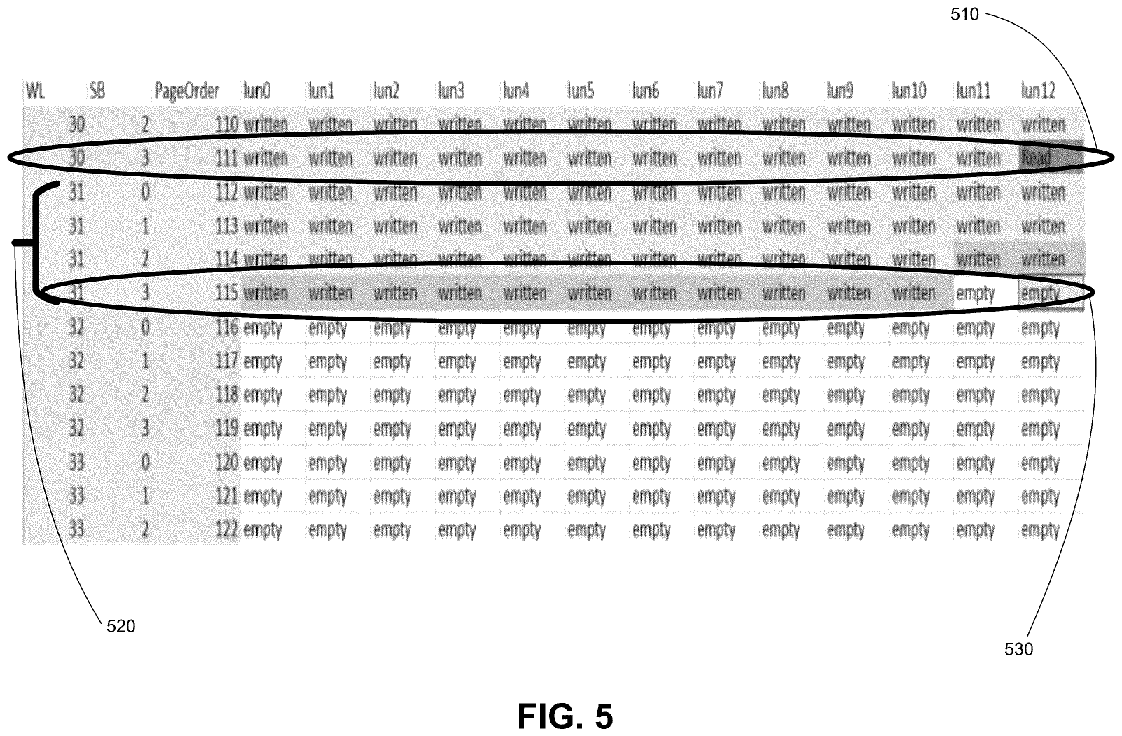

At operation 402, the processing logic (e.g., scan module 113) can detect a read disturb scan trigger event. Read disturb scans can be triggered when a read count satisfies (e.g., is equal to) a threshold read count. For example, the processing logic can utilize a counter to count a number of read operations performed on a given memory device since a previous read disturb scan was performed in the memory sub-system 110. Once that count reaches the threshold read count, the processing logic can detect the trigger event. Scan module 113 can further identify a location of a current read operation. More specifically, scan module 113 can identify a wordline at which the current read operation is executing. FIG. 5 illustrates an example instance of pages written to and read from a plurality of dies, in accordance with some embodiments of the present disclosure. As illustrated by element 510 of FIG. 5, the current read operation is executing on worldline 30 of Lun12.

At operation 404, scan module 113 can identify a subsequent wordline that follows the wordline at which the current read operation is executing. For example, as illustrated by element 520 of FIG. 5, since the current read operation is executing at wordline 30, scan module 113 can determine that the subsequent wordline is wordline 31.

At operation 406, scan module 113 can determine whether the subsequent wordline contains at least one empty page. For example, referring to FIG. 5, scan module 113 can determine whether wordline 31 contains at least one empty page.

If, at operation 406, scan module 113 determines that the subsequent wordline contains at least one empty page, then, at operation 408, scan module 113 can select at random an empty page within the subsequent wordline and scan the selected page. For example, referring to element 530 of FIG. 5, scan module 113 can determine that wordline 31 includes an empty page. Therefore, scan module 113 can scan the empty page located at wordline 31. Scan module 113 can return to operation 402.

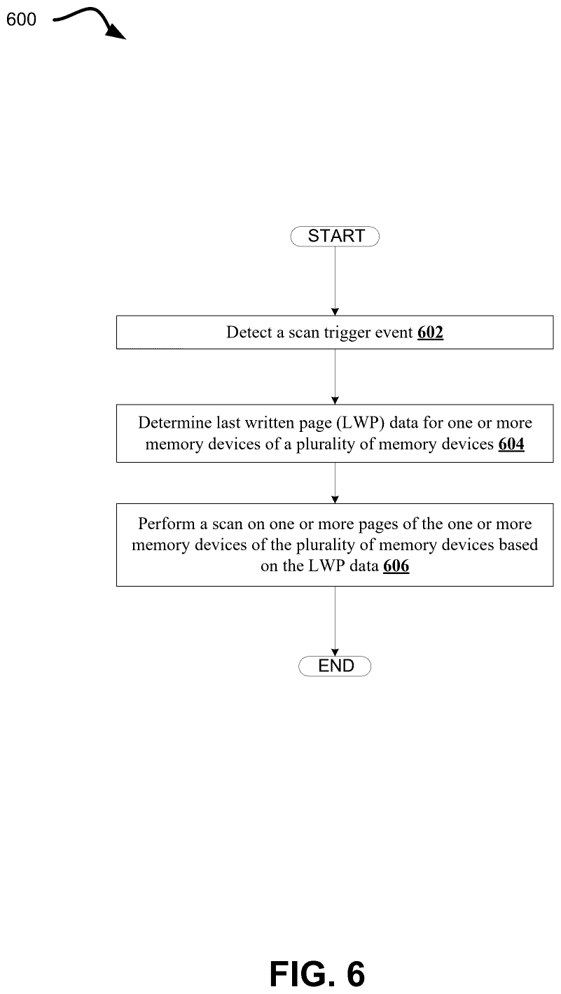

FIG. 6 is a flow diagram of an example method 600 for last written page (LWP) handling for open cursor block scans, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by the scan module 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 602, the processing logic can detect a scan trigger event for at least one of a media scan and/or a read disturb scan.

At operation 604, the processing logic can determine LWP data for one memory devices of a plurality of memory devices. In particular, the processing logic can determine the LWP of each die of a plurality of dies. Data that indicates the LWP of each die can be stored locally within the memory device (e.g., in local memory 119 of memory sub-system controller 115). Therefore, to determine the LWP of each die, scan module 113, for example, can perform one or more lookup operations on local memory 119.

At operation 606, the processing logic can perform a scan on one or more pages of one or more memory devices (e.g., dies) of the plurality of dies based on the LWP data. When the scan trigger event pertains to a media scan, the processing logic can identify, for each die, a sub-block candidate group of four pages that follow the LWP of the die. The processing logic can randomly select a page from the sub-block candidate group, referred to as the common page, and determine, for each die, whether the sub-block candidate group associated with the die includes the common page. When the sub-block candidate group includes the common page, the processing logic can scan the common page. However, when the sub-block candidate group does not include the common page, the processing logic can identify a page that is located at a page order that is four less than a page order associated with the common page. The processing logic can scan the page that is located at a page order that is four less than the page order associated with the common page.

Additionally or alternatively, when the scan trigger event pertains to a read disturb scan, the processing logic can identify a wordline on which a current read operation is executing. The processing logic can identify a subsequent wordline to the wordline on which the current read operation is executing. The processing logic can determine whether the subsequent wordline contains an empty page. If the subsequent wordline contains an empty page, the processing logic can scan the empty page.

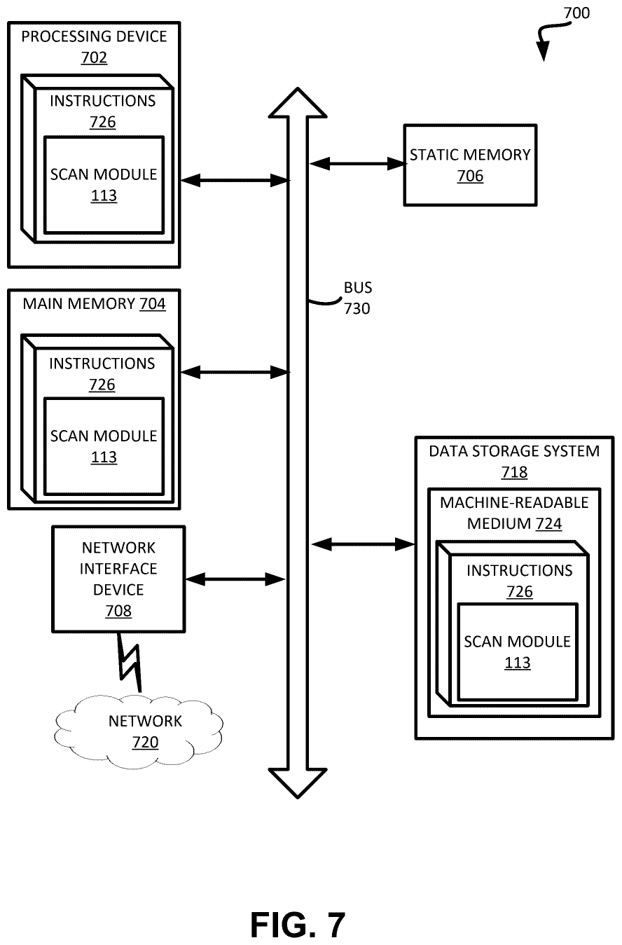

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the scan module 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or RDRAM, etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1.

In one embodiment, the instructions 726 include instructions to implement functionality corresponding to a scan module (e.g., the scan module 113 of FIG. 1). While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a plurality of memory devices; and
a processing device operatively coupled to the plurality of memory devices and configured to perform operations comprising:
detecting a scan trigger event;
determining last written page (LWP) data for one or more memory devices of the plurality of memory devices; and
performing a scan on one or more pages of the one or more memory devices of the plurality of memory devices based on the LWP data.

2. The system of claim 1, wherein the scan comprises a media scan, and wherein the scan trigger event for the media scan comprises an expiration of a pre-determined time interval.

3. The system of claim 2, wherein the processing device is configured to determine the LWP data for a page stripe comprising at least one block from each of the plurality of memory devices.

4. The system of claim 2, wherein the processing device is further configured to perform operations, for each memory device of the plurality of memory devices, comprising:
based on detecting the scan trigger event, identifying respective candidate groups of pages following a LWP for each memory device;
selecting a common page from a candidate group of a first memory device;
determining whether the respective candidate groups comprise the common page; and
based on determining that the respective candidate groups comprise the common page, scanning the common page.

5. The system of claim 4, wherein the processing device is further configured to perform operations, for each memory device of the plurality of memory devices, comprising:
based on determining that the respective candidate groups do not comprise the common page, identifying a page that is four less than the common page; and
performing the media scan on the page that is four less than the common page.

6. The system of claim 1, wherein the scan comprises a read disturb scan, and wherein the scan trigger event for the read disturb scan comprises a current read count for a memory device satisfying a threshold criterion.

7. The system of claim 6, wherein the processing device is configured to determine the LWP data for each of the plurality of memory devices.

8. The system of claim 6, wherein the processing device is further configured to perform operations comprising:
based on detecting the scan trigger event for a wordline of a memory device of the plurality of memory devices, identifying a subsequent wordline that follows the wordline;
determining, based on the LWP data, whether the subsequent wordline comprises an empty page; and
based on determining that the subsequent wordline comprises an empty page, performing the read disturb scan on the empty page.

9. A method comprising:
detecting a scan trigger event in a memory sub-system;
determining last written page (LWP) data for one or more memory devices of a plurality of memory devices in the memory sub-system; and
performing a scan on one or more pages of the one or more of the plurality of memory devices based on the LWP data.

10. The method of claim 9, wherein the scan comprises a media scan, and wherein the scan trigger event for the media scan comprises an expiration of a pre-determined time interval.

11. The method of claim 10, further comprising, for each memory device of the plurality of memory devices:
determining the LWP data for a page stripe comprising at least one block from each of the plurality of memory devices;
based on detecting the scan trigger event, identifying respective candidate groups of pages following a LWP for each memory device;
selecting a common page from a candidate group of a first memory device;
determining whether the respective candidate groups comprise the common page; and
based on determining that the respective candidate groups comprise the common page, scanning the common page.

12. The method of claim 11, further comprising, for each memory device of the plurality of memory devices:
based on determining that the respective candidate groups do not comprise the common page, identifying a page that is four less than the common page; and
performing the media scan on the page that is four less than the common page.

13. The method of claim 9, wherein the scan comprises a read disturb scan, and wherein the scan trigger event for the read disturb scan comprises a current read count for a memory device satisfying a threshold criterion.

14. The method of claim 13, further comprising, for each memory device of the plurality of memory devices:
determining the LWP data for each of the plurality of memory devices;
based on detecting the scan trigger event for a wordline of a memory device of the plurality of memory devices, identifying a subsequent wordline that follows the wordline;
determining, based on the LWP data, whether the subsequent wordline comprises an empty page; and
based on determining that the subsequent wordline comprises an empty page, performing the read disturb scan on the empty page.

15. A non-transitory computer-readable storage medium comprising instructions that, when executed by a processing device, cause the processing device to perform operations comprising:
detecting a scan trigger event in a memory sub-system;
determining last written page (LWP) data for one or more memory devices of a plurality of memory devices in the memory sub-system; and
performing a scan on one or more pages of the one or more of the plurality of memory devices based on the LWP data.

16. The non-transitory computer-readable storage medium of claim 15, wherein the scan comprises a media scan, and wherein the scan trigger event for the media scan comprises an expiration of a pre-determined time interval.

17. The non-transitory computer-readable storage medium of claim 16, wherein the processing device is further configured to perform operations, for each memory device of the plurality of memory devices, comprising:
determining the LWP data for a page stripe comprising at least one block from each of the plurality of memory devices;
based on detecting the scan trigger event, identifying respective candidate groups of pages following a LWP for each memory device;
selecting a common page from a candidate group of a first memory device;
determining whether the respective candidate groups comprise the common page; and
based on determining that the respective candidate groups comprise the common page, scanning the common page.

18. The non-transitory computer-readable storage medium of claim 17, wherein the processing device is further configured to perform operations, for each memory device of the plurality of memory devices, comprising:
based on determining that the respective candidate groups do not comprise the common page, identifying a page that is four less than the common page; and
performing the media scan on the page that is four less than the common page.

19. The non-transitory computer-readable storage medium of claim 15, wherein the scan comprises a read disturb scan, and wherein the scan trigger event for the read disturb scan comprises a current read count for a memory device satisfying a threshold criterion.

20. The non-transitory computer-readable storage medium of claim 19, wherein the processing device is further configured to perform operations, for each memory device of the plurality of memory devices, comprising:
determining the LWP data for each of the plurality of memory devices;
based on detecting the scan trigger event for a wordline of a memory device of the plurality of memory devices, identifying a subsequent wordline that follows the wordline;
determining, based on the LWP data, whether the subsequent wordline comprises an empty page; and
based on determining that the subsequent wordline comprises an empty page, performing the read disturb scan on the empty page.
